(19) United States
(12) Patent Application Publication
(10) Pub. No.: US 2026/0209990 A1
(43) Pub. Date: Jul. 23, 2026

(54) STRUCTURE COMPRISING A HIGH THERMAL CONDUCTIVITY BORON ARSENIDE LAYER, AND METHOD OF MANUFACTURE

(71) Applicant: Soitec, BERNIN (FR)

(72) Inventor: Christophe Figuet, BERNIN (FR)

(21) Appl. No.: 19/134,868

(22) PCT Filed: Dec. 5, 2023
(86) PCT No.: PCT/EP2023/084395

§ 371 Date: Jun. 2, 2025

(30) Foreign Application Priority Data
Dec. 8, 2022 (FR) FR2212999

(51) Int. Cl. C30B 29/40; C30B 25/18; C30B 31/22; C30B 33/02; H10W 40/00; H10W 40/25

(52) U.S. Cl. CPC C30B 29/40; C30B 25/18; C30B 31/22; C30B 33/02; H10W 40/03; H10W 40/253

(57) ABSTRACT

A structure for microelectronic applications, extending along an extension plane, includes a crystalline boron arsenide BAs layer having two dimensions, each of at least 2 cm, respectively along two directions normal to each other and included in the extension plane.

### CROSS-REFERENCE TO RELATED APPLICATIONS

This application is a national phase entry under 35 U.S.C. § 371 of International Patent Application PCT/EP2023/084395, filed Dec. 5, 2023, designating the United States of America and published as International Patent Publication WO 2024/121176 A 1 on Jun. 13, 2024, which claims the benefit under Article 8 of the Patent Cooperation Treaty of French Patent Application Serial No. FR2212999, filed Dec. 8, 2022.

### TECHNICAL FIELD

The present disclosure relates to a semiconductor crystal of high thermal conductivity that takes the form of a substrate for applications in the semiconductor industry, particularly in the thermal management of semiconductor devices formed on such a substrate.

### BACKGROUND

Heat dissipation is a paramount issue in the electronics and semiconductor industries. The high power and high density of components in integrated circuits increase the temperature of the electronic devices incorporating them, resulting in overheating and failures. In order to improve the reliability of these devices, it is necessary for the heat generated in integrated circuits to be spread and removed rapidly, an aspect of electronic devices known as thermal management.

Materials with high thermal conductivity are proposed to remove the heat produced by integrated circuits. Mention may be made, in particular, of aluminum nitride (AIN) and silicon carbide (SiC), with respective thermal conductivities of about 285 W/m.K and 300 W/m.K, which are insufficient for satisfactory thermal management. Diamond has a high thermal conductivity of about 2000 W/m.K but suffers from its high cost and difficulty of implementation in integrated devices.

In this context, the thermal characteristics of boron arsenide (BAs) have turned out to be attractive, with, in particular, a thermal conductivity evaluated theoretically at around 1400 W/m.K and measured experimentally at about 1200 W/m.K, thus much higher than the materials conventionally used in the field, such as copper, which has a thermal conductivity of around 400 W/m.K.

However, boron arsenide is notoriously difficult to synthesize and can only offer its maximum thermal conductivity in a perfect crystalline form, free of defects and impurities that scatter phonons in the material, drastically lowering its thermal conductivity to just a few hundred watts per meter-kelvin. On this subject, see the publication by Fei Tian and Zhifeng Ren, “High Thermal Conductivity in Boron Arsenide: From Prediction to Reality” in Angew. Chem. 2019, 131, 2-10.

Document US 2021/0035885 A1 describes an integrated circuit disposed in or over a BAs substrate, and also a process for the crystalline growth of a BAs single crystal. The BAs growth process uses a chemical vapor transport technique in the presence of a boron phosphide BP single crystal used as seed crystal, at temperatures of around 1000° C. for reaction periods in a sealed quartz tube extending over 5 weeks, which periods were repeated until high-quality BAs crystals with thermal conductivities of up to 1300 W/m.K at room temperature were obtained.

Document US 2021/0269318 A1 describes a similar process, with a first chemical vapor transport reaction in a quartz tube using BAs single crystals of micrometer sizes as seed crystals, at temperatures of around 800° C. for 2 weeks, followed by a second reaction similar to the first using the better quality crystals obtained following the first reaction as seed crystals, to obtain BAs crystals of millimeter sizes.

It is observed that there is a great need to provide boron arsenide in high-quality crystalline form, preferably in monocrystalline form, suitable for use in the production of electronic circuits, and, in particular, for the thermal management of these circuits. More specifically, it is particularly desirable to provide boron arsenide in the form of a substrate or a layer capable of being transferred onto a substrate capable of accommodating a plurality of electronic circuits, such as a 6″, 8″, or 12″ silicon wafer.

### BRIEF SUMMARY

A first objective of the present disclosure is to provide a structure for microelectronic applications consisting at least in part of a crystalline layer of boron arsenide of chemical formula BAs, of zinc-blende structure. A second objective is to provide a fabrication process for obtaining such a structure, capable of accommodating a plurality of electronic circuits or already provided with such circuits.

With a view to achieving this objective, a first aspect of the present disclosure is a structure for microelectronic applications, extending along an extension plane (xy), comprising a crystalline boron arsenide BAs layer having two dimensions, each of at least 2 cm, along, respectively, two directions normal to each other and included in the extension plane.

One advantage of the structure according to the present disclosure derives from the fact that it has a very high thermal conductivity while having a geometry suitable for placing it in intimate contact with a plurality of electronic circuits in a collective fabrication process compatible with the conventional fabrication techniques of the microelectronics industry. Thus, this structure is capable of efficiently discharging the heat produced by electronic circuits integrated on this structure or the heat produced by electronic circuits with which this structure is placed in intimate contact, and therefore of improving the reliability of these electronic circuits.

According to additional non-limiting characteristics of the first aspect of the present disclosure, considered individually or in any technically feasible combination:
the crystalline boron arsenide BAs layer may be monocrystalline;
the structure may further comprise a 3C polytype silicon carbide layer in direct contact with the boron arsenide BAs layer;
one of the crystalline boron arsenide BAs layer and the 3C polytype silicon carbide layer may comprise an implantation layer comprising hydrogen and/or helium;
the structure may comprise a temporary support attached to the crystalline boron arsenide BAs layer;
the temporary support may be an adhesive thermal tape; and
the structure may comprise a layer of stressor material between the temporary support and the crystalline boron arsenide BAs layer.

The present disclosure extends to an electronic device integrating the structure. According to additional non-limiting characteristics of the electronic device according to the present disclosure, considered individually or in any technically feasible combination:
the electronic device may comprise a semiconductor substrate integrating at least one electronic circuit juxtaposed to the crystalline boron arsenide BAs layer;
the crystalline boron arsenide BAs layer may be joined to the semiconductor substrate by direct bonding;
the electronic device may comprise a transistor configured to comprise a channel that is formed in the crystalline boron arsenide BAs layer.

A second aspect of the present disclosure relates to the fabrication of a structure comprising a crystalline layer of boron arsenide of chemical formula BAs, so as to conveniently and economically produce boron arsenide BAs layers with dimensions compatible with the industrial requirements of the semiconductor industry.

With a view to achieving this object, a first aspect of the present disclosure is a process for fabricating a structure for microelectronic applications, comprising the steps of providing a 3C polytype silicon carbide layer having a flat surface and of growing a crystalline boron arsenide BAs layer on the silicon carbide layer, the silicon carbide layer (3C-SiC_{lay}) and the crystalline boron arsenide BAs layer having two dimensions, each of at least 2 cm along, respectively, two directions normal to each other and included in an extension plane parallel to the flat surface of the silicon carbide layer.

The process according to the present disclosure is advantageous in that it makes it possible to obtain boron arsenide BAs layers of large dimensions, on the order of a centimeter or tens of centimeters, by employing techniques that are well understood in the semiconductor industry. This process makes it possible to envisage a standardized and mass fabrication of structures comprising boron arsenide BAs layers suitable for being integrated in a process for fabricating electronic circuits. The dimensions of the layers obtained make it possible to envisage the collective fabrication of a plurality of semiconductor circuits on the same boron arsenide BAS layer obtained according to the process of the present disclosure.

According to additional non-limiting characteristics of the second aspect of the present disclosure, considered individually or in any technically feasible combination:
the process may further comprise the formation of a detachment layer and the detachment, at the detachment layer, of at least one portion of the crystalline boron arsenide BAs layer with respect to at least one portion of the silicon carbide layer;
the formation of the detachment layer may comprise a step of introducing a light species into the silicon carbide layer so as to define therein a weakened plane before the step of growing the crystalline boron arsenide BAs layer, followed by a heat treatment for splitting the silicon carbide layer into two parts at the weakened plane;
the step of growing the crystalline boron arsenide BAs layer on the silicon carbide layer may be carried out at a temperature below 850° C.;
it is possible to grow the crystalline boron arsenide BAs layer to a thickness of between 100 μm and 2000 μm;
the formation of the detachment layer may comprises a step of introducing a light species into the crystalline boron arsenide BAs layer so as to define therein a weakened plane, followed by a splitting heat treatment of the boron arsenide BAs layer into two parts at this weakened plane;
it is possible to grow the crystalline boron arsenide BAs layer to a thickness of between 0.5 μm and 5 μm;
the formation of the detachment layer may comprise a step of covering the silicon carbide substrate with a layer (vdW_{lay}) of van der Waals material before the step of growing the crystalline boron arsenide BAs layer;
the layer of van der Waals material may comprise a graphene layer; and
the process may further comprise a step of detaching the boron arsenide BAs layer from the silicon carbide layer by traction applied to an intermediate support attached to the boron arsenide BAs layer.

The present disclosure extends to a process for fabricating a microelectronic circuit, comprising the process for fabricating a structure described above, and further comprising the steps of joining the crystalline boron arsenide BAs layer to a semiconductor substrate in which a plurality of electronic circuits are integrated and a step of separating the electronic circuits from each other after the joining step.

### BRIEF DESCRIPTION OF THE DRAWINGS

Other features and advantages of the present disclosure will become apparent from the following detailed description of example embodiments of the present disclosure, which is given with reference to the appended figures, in which:

FIGS. 1A and 1B represent a first structure comprising a crystalline boron arsenide layer according to the present disclosure and the process of fabricating same;

FIGS. 2A and 2B represent a second structure comprising a crystalline boron arsenide layer according to the present disclosure and the process of fabricating same;

FIGS. 3A and 3B represent a third structure comprising a crystalline boron arsenide layer according to the present disclosure and the process of fabricating same;

FIGS. 4A and 4B represent a fourth structure comprising a crystalline boron arsenide layer according to the present disclosure and the process of fabricating same;

FIGS. 5A and 5B represent a particular implementation of the structure from FIG. 4;

FIGS. 6A and 6B represent a fifth structure comprising a crystalline boron arsenide layer according to the present disclosure and the process of fabricating same;

FIG. 7 represents a first particular implementation of the structure from FIGS. 1A-6B;

FIG. 8 represents a second particular implementation of the structure from FIGS. 1A-6B; and

FIGS. 9A and 9B illustrate the geometry of the crystalline boron arsenide layers from FIGS. 1A-6B.

### DETAILED DESCRIPTION

As seen in the section on the technological background of the present disclosure, one difficulty in growing crystals, and therefore crystalline layers, of boron arsenide BAs is that there is no substrate that can be used as a seed for the crystalline growth of this material in the form of thin films or wafers that can be used as such for the integration of electronic circuits. In fact, up to now, seeds of micrometer sizes are usually employed, leading to the slow growth of crystals of uncontrolled geometries.

However, it has been realized that one known but little used material in the semiconductor industry has crystalline parameters compatible with those of boron arsenide and can therefore be used as a base for the crystalline growth thereof: this is the 3C polytype of silicon carbide, also referred to as β-SiC or 3C-SiC, of sphalerite type. It will be noted, in particular, that the lattice parameter of 3C-SiC is 4.3596 Å, close enough to the lattice parameter of 4.777 Å of BAs to be used as seed for crystalline growth.

This material can, for example, be fabricated by growing on a monocrystalline silicon Si substrate of (001) crystalline orientation, typically in the form of generally circular wafers, in dimensions compatible with the conventional processes of the semiconductor industry, for example, 6 inches, 8 inches, 12 inches, or 300 mm. Specifically, owing to the good compatibility of 3C-SiC with Si, in particular, as regards their coefficients of thermal expansion, respectively, 3.8 10⁻⁶ K⁻¹ and 2.6 10⁻⁶ K⁻¹, it is easy to increase the sizes of the substrates of the 3C-SiC/Si composite structures. As is well known in the semiconductor industry, wafers may consist of insulating or semiconductor substrates in the form of discs, with two substantially parallel and flat opposite surfaces, and also a notch or flat spot at the periphery, serving as a marker for the crystalline orientation of the substrate, if necessary.

### First Embodiment

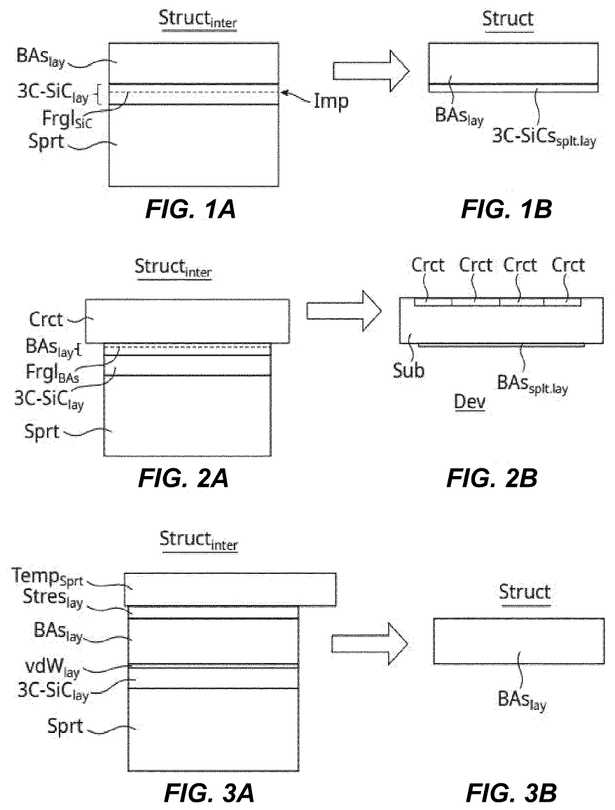

A first embodiment of the present disclosure is illustrated by FIG. 1.

FIG. 1A represents an intermediate structure Structᵢₙₜₑᵣ obtained by a process comprising the steps detailed below.

On a support Sprt, for example, a monocrystalline silicon substrate of (001) orientation, a layer 3C-SiC_{lay} of 3C-SiC is grown according to conventional heteroepitaxial methods to a thickness of between 0.3 and 5 μm, preferably between 0.5 and 1.5 μm, for example, by CVD or MOCVD, respectively, chemical vapor deposition and metalorganic chemical vapor deposition.

On the 3C-SiClay layer, a crystalline layer BASlay of boron arsenide of chemical formula BAs is grown by an atmospheric-pressure MOCVD method using boron precursor gases such as diborane B₂H₆ or triethylboron B(C₂H₅)₃ evaporated in hydrogen, and arsine (AsH₃) or tertiarybutylarsine (TBAs) or trimethylarsenic (TMAs), hydrogen being used as carrier gas at reduced pressure and at a growth temperature of between 450° C. and 800° C., preferably between 500° C. and 750° C.

Alternatively to the MOCVD or MBE method, it is possible to grow the crystalline BAs layer BASlay on the 3C-SiC_{lay} layer by a CVT (chemical vapor transport) method similar to that described by Tian and mentioned in the “Technological background” section, an important difference arising from the fact that the 3C-SiC layer is used as seed. To achieve this, use may be made, as sources of arsenic and boron, of arsenic and boron in elemental form or in boron arsenide BAs form, optionally in combination with and, as transport agent, iodine I₂, which is capable of reversibly forming boron triiodide BI₃ with boron in elemental form B, and with boron arsenide BAs, and in the same manner, capable of forming arsenic triiodide AsI₃. In addition to iodine I₂, ammonium iodide NH₄I and tellurium tetraiodide TeI₄ can be used as transport agent. Placing the 3C-SiC layer, the source and the transport agent in a sealed reactor with a temperature gradient leads to the growth of BAs in crystalline form on the 3C-SiC layer placed on the cold side of the reactor, and thus to a BAs layer in crystalline form. Temperature ranges such as 613° C.-850° C. or 613° C.-900° C., or else 727°C.-850° C. or 727°C.-900° C. may be considered.

According to either of the MOCVD method and the CVT method, a crystalline layer, preferably monocrystalline layer, of BAs having a thickness of 300 to 1000 μm, preferably 500 to 800 μm, is grown. Such a thickness makes it possible to obtain a BAs layer that will be self-supporting: it will not require the use of a temporary support for the handling thereof.

An advantage of this process over the methods of the prior art lies in the use of a 3C-SiC layer epitaxially grown on a silicon substrate as seed, which makes it possible to obtain crystalline and preferably monocrystalline BAs layers of relatively large surface areas, for example, by using a silicon wafer of 6 inches, 8 inches, 12 inches, i.e., 150 mm, 200 mm or even 300 mm in diameter, respectively, as the surface for forming the 3C-SiC layer. It is thus possible to obtain crystalline layers of boron arsenide having a dimension of at least 2 cm in a given direction, and more, depending on the size of the substrate used, for example, 4 inches, 6 inches, 8 inches, 12 inches, i.e., 100 mm, 150 mm, 200 mm or even 300 mm, respectively, if wafers of these diameters are used, the shape of the 3C-SiC layer also not being limited to the typical circular shape of a semiconductor substrate wafer. The crystalline layers of boron arsenide according to the present disclosure may also have a flat surface having an area greater than 1cm² , preferably greater than 10cm² , more preferably greater than 100cm² . The crystalline layers of boron arsenide according to the present disclosure may also have a flat surface in which a circle with a diameter of greater than 2 cm, preferably greater than 5 cm, preferably greater than 10 cm is inscribed.

At this stage, it is desirable to be able to detach the layer BA_{Slay} from the support Sprt, for example, by carrying out the SMART CUT™ method. To this end, prior to the growth of the layer BA_{Slay}, it was possible to prepare the layer 3C-SiC_{lay} by introducing therein one or more light species such as hydrogen or helium. This introduction may correspond to a hydrogen implantation, that is to say a hydrogen ion bombardment through a planar face of the layer 3C-SiC_{lay}. This face may optionally be provided with a protective layer formed before the ion bombardment, which may optionally be removed thereafter. As is known per se, and as illustrated in FIG. 1A, the implanted H⁺ hydrogen ions form an implantation layer Imp within the layer 3C-SiC_{lay} and are intended to form a weakened plane Frglsic defined by this implantation layer and dividing the layer 3C-SiC_{lay} into two portions, one on the support side, the other on the side of the layer BA_{Slay}, which will be separated from the support at this weakened plane at a later stage. The implantation layer Imp is considered to be a layer for detaching the layer BA_{Slay} with respect to its support Sprt and a portion of the layer 3C-SiC_{lay}.

The nature, the dose of the implanted species and the implantation energy are chosen according to the thickness of the layer that it is desired to transfer. In the case of the layer 3C-SiC_{lay}, it will be possible to choose to implant a dose of hydrogen of between 10¹⁶ and 5×10¹⁷ at/cm² with an energy of between 30 and 300 keV in order to define a weakened plane at a depth of about 200 to 2000 nm. When such a process is carried out, including the formation of a weakened plane, it is preferable to keep the growth temperature of the BAs layer below 850° C., for example, between 613° C. and 850° C. or between 727° C. and 850° C., so as to limit the risks of uncontrolled cleavage of the layer 3C-SiC_{lay}.

FIG. 1B illustrates a structure Struct comprising a crystalline boron arsenide layer BASlay obtained following the detachment of the support Sprt, and that is in the form of a wafer.

The step of detaching the support Sprt is carried out by splitting at the weakened plane Frglsic, which can be brought about by applying to the intermediate structure Structᵢₙₜₑᵣ a heat treatment in a temperature range of between 850° C. and 920° C., preferably between 900° C. and 920° C., to enable the detachment of the BA_{Slay} layer while avoiding a phase change of the BAs layer to a B₁₂Aₛ₆ layer. Furthermore, it is preferable to carry out this heat treatment in an atmosphere having an excess pressure of arsenic (AsH₃, TBAs, TMAs) in order to avoid desorption of arsenic. Instead of or in addition to the heat treatment, this step may comprise the application of a blade or a jet of gaseous or liquid fluid, or any other mechanical force to the weakened plane Frglsic.

As an alternative to carrying out the SMART CUT™ process detailed above, the step of detaching a portion of the donor substrate may be replaced by a step of mechanical-chemical thinning of the support Sprt and, optionally, of all or part of the layer 3C-SiC_{lay}.

Whether the removal of a portion of the thickness of the donor substrate is carried out by thinning or by splitting, it is possible to apply to the structure Struct thus formed any type of finishing treatment for adapting the layer BA_{Slay} to thickness, thickness uniformity, roughness or crystalline quality specifications or to any other type of specifications.

In the present example where the SMART CUT™ process is employed by splitting the 3C-SiC layer, the structure Struct consists of the crystalline boron arsenide layer BA_{Slay} and a portion of the 3C-SiC layer that was used as seed crystal for its growth. It is of course possible to completely remove the 3C-SiC layer, for example, by mechanical-chemical thinning, in which case the structure Struct consists only of the crystalline boron arsenide layer BA_{Slay}.

The example taken for this embodiment consists of a BAs layer with a thickness of between 200 and 1000 μm. Alternatively, this thickness could be between 0.5 and 2000 μm. A thick layer is self-supporting, a thin layer may have a certain flexibility during handling, depending on its lateral dimensions, and may therefore need to be directly joined to a permanent support or else to be joined to a flexible or rigid auxiliary support temporarily, in order to facilitate the handling thereof. Such a scenario will be dealt with in the following embodiments, in particular, the second and fourth embodiments, which can be combined with this first embodiment.

The crystalline boron arsenide layer BASlay finally obtained reproduces the shape and dimensions of the 3C-SiC layer that was used as seed to grow it, and that itself reproduces, where appropriate, the shape and dimensions of the silicon substrate that was used as a base for its formation. It is convenient and appropriate to use a silicon wafer of substantially circular shape widely available from semiconductor material suppliers; but any type of support capable of growing the 3C-SiC layer is suitable, be it a portion of a silicon substrate or any other material of arbitrary shape, preferably extending in a plane so as to grow a BAs layer having a flat geometric configuration suitable for use in the semiconductor industry. It is possible, for example, to characterize the layer obtained according to the present disclosure as forming a wafer, that is to say as a component having two dimensions in two directions normal to one another located in the same plane of extension that are each at least ten times, preferably at least one hundred times, more preferably at least 1,000 times and even more preferably at least 10,000 times greater than a thickness of this element, this thickness being considered as a dimension of this element in a direction perpendicular to the plane or to the two directions normal to one another. This perpendicular direction is also perpendicular to a flat surface of the 3C-SiC layer and to a flat surface of its substrate, the silicon wafer in the present example. In addition, these two dimensions are each preferably greater than 2 cm, more preferably greater than 5 cm, even more preferably greater than 10 cm.

FIGS. 9A and 9B illustrate this geometry, with a crystalline boron arsenide layer BASlay obtained by any one of the above embodiments, extending in a plane xy perpendicular to a direction z, the plane xy being defined by the directions x and y, the directions x, y and z forming a right-handed Cartesian system. FIG. 9A illustrates the layer BA_{Slay} seen in the z direction, the xy plane lying in the plane of FIG. 9B; FIG. 9B illustrates a cross-sectional view along the xz plane of the layer BA_{Slay} passing through the axis AA′ defined in FIG. 9A.

### Second Embodiment

FIGS. 2A and 2B illustrate a second embodiment of the invention, similar to the first embodiment, so that the description below will concentrate on the differences from the first embodiment, and reference may be made to the description of the first embodiment for the common elements.

In this embodiment, the layer BAs is thinner than in the first embodiment, with a thickness of between 0.5 and 5 μm, preferably 1 to 2 μm. In addition, as illustrated in FIG. 2A, the splitting plane for separating the layer BA_{Slay} from the support Sprt is not defined in the layer 3C-SiC_{lay} but in the layer BA_{Slay} itself, it is then denoted as Frgl_{BAs} in FIG. 2A, so that the splitting, brought about as explained in the first embodiment, occurs within the layer BA_{Slay} and only one portion BA_{Ssplt.lay} of this layer will ultimately be retained, as illustrated in FIG. 2B. The implantation layer Imp of the first embodiment is this time formed in the layer BA_{Slay}, this time as a layer for detaching one portion only (the portion BA_{Ssplt.lay} defined below) of the layer BA_{Slay} with respect to the layer BA_{Slay} of the support.

In this embodiment, the layer BA_{Slay} is joined to the back face of a semiconductor substrate Sub, on a front face of which a plurality of electronic circuits Crct are integrated, before the step of detaching the support Sprt, this makes it possible to avoid the difficulties associated with handling a layer of this thickness, which is generally flexible and fragile. These circuits are intended to be separated from one another during a step referred to as “dicing,” which consists in separating from one another various electronic circuits formed on a common support. When mention is made of the integration of an electronic circuit on a face of a semiconductor substrate, this may mean that the electronic circuit comprises a transistor, the channel of which is formed in the volume of the semiconductor substrate, which substrate may consist of a wafer of semiconductor material or a layer of semiconductor material supported by a support, as in the case of an SOI type structure.

Preferably, before the joining step, the semiconductor substrate Sub on which the circuits are integrated is thinned via its back face, for example, to less than 300 μm, preferably 200 μm, so as to promote heat removal. The semiconductor substrate may consist of any semiconductor material usually used in the semiconductor industry, such as a silicon wafer, optionally of crystalline orientation (100). In the case where the circuits are fabricated on a substrate of SOI (silicon-on-insulator) type comprising a semiconductor layer supported by a base substrate by means of an electrically insulating layer, it is also possible to chemically remove the entire base substrate and selectively stop the chemical etching at the electrically insulating layer.

The layer BA_{Slay} can be joined to the substrate Sub of the electronic circuits Crct by means of an adhesive substance, which is a good heat conductor, for example, comprising silver. Preferably, joining can be carried out through direct bonding by intimate contacting at an interface between one face of the BAs layer and the back face of the semiconductor substrate Sub. Beforehand, the free face of the layer BA_{Slay} and the back face of the substrate Sub may be prepared so as to allow direct bonding by placing in intimate contact, for example, by molecular adhesion. It is thus possible to form a dielectric layer such as a layer of silicon dioxide (not shown here) on one or other of the contacting faces of the circuit Crct and of the layer BA_{Slay}, or else both, in order to facilitate joining.

As is well known per se, during a molecular adhesion process, the surfaces to be adhered to one another (one and/or the other optionally being covered with a dielectric layer), which are perfectly clean, flat and smooth, are brought into intimate contact in order to favor the development of molecular bonds, for example, of van der Waals or covalent type. The joining of the two bodies is thus achieved without the use of an adhesive. The joining may comprise the application of a low-temperature heat treatment (for example, between 50° C. and 300° C., typically 100° C.) making it possible to strengthen the bonding energy. Following the adhesion and the step of splitting at the weakened plane, a part BA_{Ssplt.lay} of the layer BA_{Slay} remains attached to the circuit Crct, as illustrated in FIG. 2B.

One advantage of using direct adhesion is to avoid the formation of an adhesive layer between the circuit Crct and the layer BA_{Ssplt.lay}, which is a worse conductor than the latter. If this solution is not feasible, for technical or economic reasons, it is of course possible to use an adhesive layer even if it is not the most optimal technical solution from the point of view of heat exchanges.

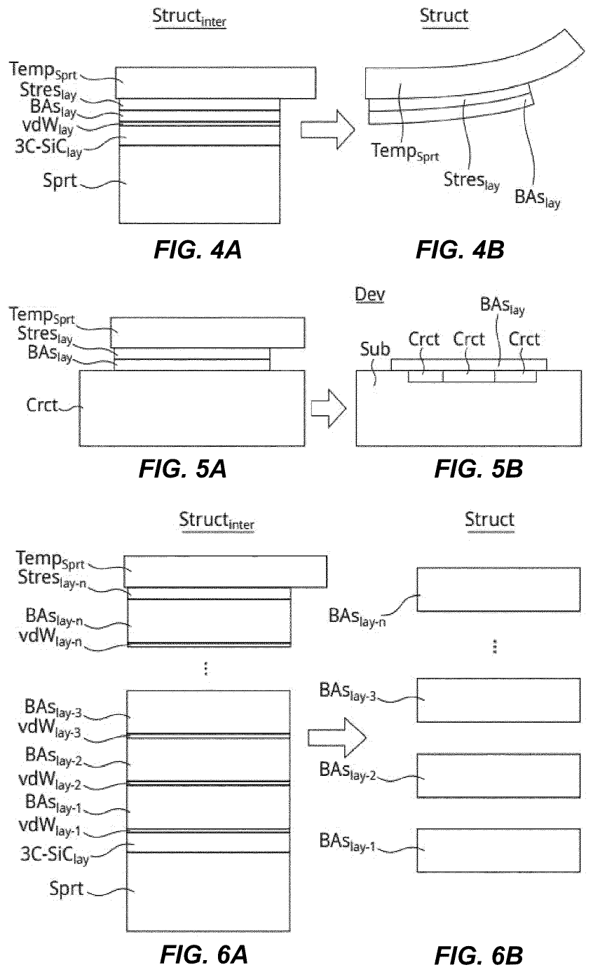

In this embodiment, as an alternative to joining the BAs layer to an electronic circuit, it is possible to join the BAs layer to a rigid support such as a wafer of semiconductor material or to a flexible support such as an adhesive thermal tape, as will be seen in the case of the fourth embodiment illustrated in FIGS. 4A and 4B. It is also possible to join the BAs layer to the front face of the semiconductor substrate rather than on its back face.

The example taken for this embodiment consists of a BAs layer with a thickness of between 0.5 and 5 μm. Alternatively, this thickness could be between 0.5 and 2 μm.

### Third Embodiment

FIGS. 3A and 3B illustrate a third embodiment of forming a structure Struct that is in the form of a BAs wafer. Unlike the first and second embodiments, this third embodiment is based on 2DLT technology (2D material-based layer transfer technology). This is a technology developed to produce elements such as monocrystalline layers, thin films or else more complex structures, in a form detached from the substrate on which they were formed. To this end, a material referred to as a van der Waals 2D material (2D because it is essentially two-dimensional) is interposed between the element in question and its substrate, allowing subsequent detachment. In the present case, the van der Waals material is used to separate a BAs layer from a substrate on which it was grown. For the elements in common between the embodiments, reference may be made to the explanations given for the first embodiment. In particular, the growth methods described in the first embodiment are applicable and reference may be made to this first embodiment for these aspects of the present embodiment.

As illustrated in FIG. 3A, a layer of material referred to as van der Waals material is formed on a layer 3C-SiC_{lay} of 3C-SiC borne by a support Sprt. A van der Waals material is defined as a material consisting of atoms strongly bonded to each other by covalent or ionic bonds only in the plane of formation of the material, without strong bonds perpendicular to this plane. From a practical point of view, it is thus possible to use one or more layers of graphene or 2D material, preferably a monolayer, to remove a structure formed on top of the graphene layer from the support located beneath it, as detailed, for example, by Celesta Chang et al. in “Remote Epitaxy,” Nature Methods, June 2022, or else in document WO 2017/044577 A1.

The intermediate structure Structinter illustrated in FIG. 3A is formed to comprise, in this order, a support Sprt, such as monocrystalline silicon, a layer 3C-SiC_{lay} of 3C-SiC, a layer vdW_{lay} of van der Waals material such as a graphene layer, a BAs layer BA_{Slay}, and temporary support Temp_{Sprt} such as a thermal adhesive tape. Optionally, a layer Streslay of material involving a high mechanical stress such as nickel or copper facilitating the subsequent detachment at the layer vdW_{lay} may be interposed between the BAs layer and the temporary support, as illustrated in FIG. 3A. A BAs layer is considered here to be thick enough to be self-supporting, when it has a thickness similar to that of the layer of the first embodiment.

The graphene layer may be obtained, for example, by a method of wet transfer of a layer obtained by CVD onto a catalytic metal substrate or by graphite transformation of the SiC layer by sublimation of the silicon. It should be noted that the crystal pattern of the 3C-SiC layer is capable of guiding the crystalline growth of the BAs layer through the graphene layer when it is sufficiently thin, preferably from 1 to less than 10, preferably from 1 to 3 graphene sheets.

FIG. 3B illustrates the result of simple traction of the temporary support: the layer BA_{Slay} has been detached from the substrate at the layer vdW_{lay}, then the temporary substrate has been detached by the application of heat if it was an adhesive thermal tape, and the layer Stre_{Slay} has been removed chemically in a conventional manner. The self-supporting layer BA_{Slay} then forms the structure Struct by itself. It is possible to leave the layer Stre_{Slay} on the layer BA_{Slay}, depending on the applications targeted by the practitioner. The vdWlay layer is considered to be a layer for detaching the layer BA_{Slay} from its support Sprt and from the layer 3C-SiC_{lay} of 3C-SiC.

### Fourth Embodiment

FIGS. 4A and 4B illustrate a fourth embodiment of the invention, similar to the third embodiment, so that the description below will concentrate on the differences from the third embodiment, and reference may be made to the description of the third embodiment for the common elements.

Unlike the third embodiment, only a reduced thickness of BAs of between 0.5 and 5 μm, preferably 1 to 2 μm, is grown on the graphene layer, so that the layer BA_{Slay} is not self-supporting, or else is too fragile to be handled easily on its own, without auxiliary support.

In this situation, after detachment of the layer BA_{Slay} at the layer vdW_{lay}, the temporary support Temp_{Sprt} is not detached and the layer Stre_{Slay} is not removed, but the layer BA_{Slay} is kept attached to the temporary support Temp_{Sprt} until its final use. In this embodiment, the layer BA_{Slay} of BAs is supported by the temporary support Temp_{Sprt}.

### Fifth Embodiment

FIGS. 5A and 5B illustrate a use of the layer BA_{Slay} joined to a temporary support as illustrated in FIG. 4B. This embodiment can be described as a combination of the second embodiment for aspects related to joining the layer BA_{Slay} to electronic circuits Crct with the fourth embodiment for aspects related to obtaining a BAs layer attached to a temporary support and with the third embodiment for the aspect relating to removing the temporary support and layer Stre_{Slay}.

In other words, it is possible to apply one or other of the joining techniques mentioned in the second embodiment to join the layer BA_{Slay} of the fourth embodiment to one or more electronic circuits Crct integrated in a semiconductor substrate Sub, the layer BA_{Slay} being brought into contact while this layer is being handled by means of its temporary support Temp_{Sprt} as illustrated in FIG. 5A, this support and the layer Stre_{Slay} being removed after joining to the electronic circuit, so as to obtain the device Dev illustrated in FIG. 5B. Unlike the configuration illustrated in FIG. 2B, the layer BA_{Slay} is joined to the front face of the semiconductor substrate Sub, that is to say to the face on which the electronic circuits Crct are integrated. As for the second embodiment, after joining, it is possible to carry out a step of separating the electronic circuits from one another during an operation known in the microelectronics industry as “dicing.”

### Sixth embodiment

FIGS. 6A and 6B illustrate a sixth embodiment of the invention, similar to the third and fourth embodiments illustrated by FIGS. 3A-4B, but with the distinctive feature that instead of comprising only a single BAs layer, the intermediate structure comprises a stack of BAs layers each separated from the others by a layer of van der Waals material such as graphene. Reference may be made to these embodiments for the common elements.

FIG. 6A thus illustrates an intermediate structure Structᵢₙₜₑᵣ with n BAs layers BA_{Slay-x} and n layers vdW_{lay-x} of van der Waals material, x being an integer from 1 to n increasing with the distance from the support Sprt, the layer BA_{Slay-n}, the furthest from the support Sprt, being formed on a layer vdW_{lay-n} of van der Waals material and provided with a layer Stre_{Slay-n} of stressor material to which a temporary support Temp_{Sprt} is attached.

As in the third embodiment, it is possible to separate the layer BA_{Slay-n} from the intermediate structure. Subsequently, the layer vdW_{lay-n} of van der Waals material is removed, and then a new layer of stressor material is deposited on the layer BA_{Slay-(n-1)} then exposed and a new temporary support is attached thereto. The process is then repeated until the n BAs layers have been removed from the intermediate structure and form as many BAs structures in the form of wafers. This process is advantageous in that it allows greater productivity during the fabrication of the BAs wafers.

As illustrated in FIG. 6B, the BAs layers can be separated from their respective temporary supports and cleaned from their layers of stressor material. This option is appropriate when the layers BA_{Slay-x} are thick enough to be self-supporting. Alternatively, when the layers are too thin to be easily handled, they can be kept attached to their temporary support, as in the case illustrated in FIG. 4B.

### Seventh Embodiment

One application of the BAs layers described in the preceding embodiments is in the removal of heat from integrated electronic circuits. Conventionally, an integrated electronic circuit is equipped with a heat sink Sink, optionally provided with heat-removing fins Fin, in order to limit the heating of this electronic circuit during the operation thereof by removing the heat that it produces.

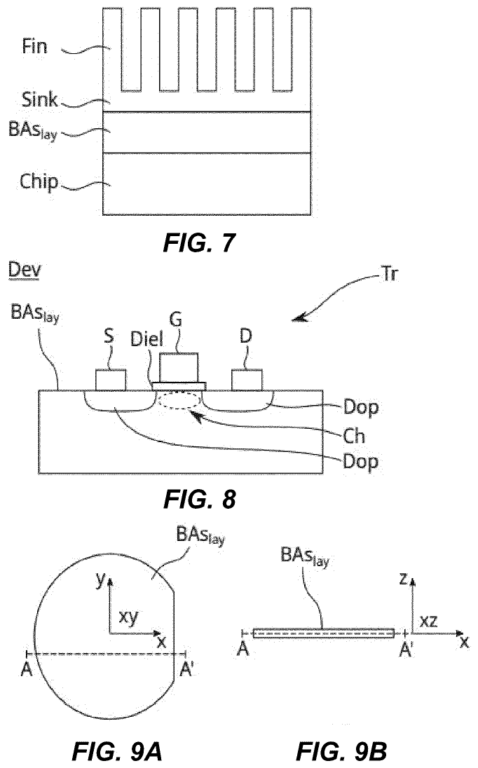

In the context of the present disclosure, a BAs layer BA_{Slay} obtained according to any one of the embodiments described above, as illustrated by FIG. 7, can be interposed between the electronic circuit and the heat sink. The advantage is to enable the removal of heat as close as possible to the circuit and to limit the appearance of hot spots, localized heat islands on the surface of the circuit. The high thermal conductivity of the BAs layer and its proximity to the circuit considerably improve the efficiency of heat removal from an electronic circuit compared to known solutions.

The layer BA_{Slay} may be located on the back face or on the front face of an integrated circuit Chip and may be attached thereto by direct bonding (without addition of an intermediate adhesive material layer) or by means of an adhesive, which is preferably a good heat conductor. Direct bonding is preferable in order to ensure intimate contact between the BAs and the electronic circuit and to promote heat exchange between the circuit and the BAs layer. An adhesive, even a relatively good heat conductor, will represent a thermal barrier when compared with the BAs crystalline layer according to the present disclosure, which is a better heat conductor.

### Eighth Embodiment

The examples of applications given so far consist in taking advantage of the high thermal conductivity of the crystalline BAs to assist in the removal of the heat produced by a circuit integrated into another semiconductor substrate such as silicon.

The present embodiment consists in taking advantage of the semiconductor characteristics of BAs, which is a III-V semiconductor, by integrating therein a device Dev comprising an electronic circuit comprising at least one transistor configured to comprise a channel that is formed in a BAs layer formed according to any of the processes described above, as illustrated by FIG. 8 with a transistor Tr integrated into a BAs layer BA_{Slay} according to any one of the preceding embodiments.

The transistor Tr comprises a source S, a drain D and a gate G, which may be formed of metals, two doping zones Dop surrounding the gate, formed superficially in the volume of the layer BA_{Slay} and in electrical contact respectively with the source and the drain, and a channel-forming zone Ch located between the two doping zones, superficially in the volume of the layer BA_{Slay}, a dielectric layer Diel insulating the gate from this channel-forming zone.

This results in optimum removal of the heat produced at any hot spots of the circuit, increasing its reliability and limiting the use of elements dedicated specifically to the removal of heat, simplifying the design and the fabrication of such circuits compared to those based on other semiconductors.

In this disclosure, the figures are not necessarily to scale. Some features and components may be shown enlarged relative to other components or in a somewhat schematic form, and some details of conventional elements may not be shown in the interest of clarity and conciseness.

The present disclosure is of course not limited to the embodiments described, and implementation variants may be applied thereto without departing from the scope of the invention as defined by the claims.

1. A structure for microelectronic applications, extending along an extension plane (xy), comprising a crystalline boron arsenide BAs layer having two dimensions, each of at least 2 cm, respectively along two directions (x, y) normal to each other and included in the extension plane (xy).

2. The structure of claim 1, wherein the crystalline boron arsenide BAs layer is monocrystalline.

3. The structure of claim 1, further comprising a 3C polytype silicon carbide layer in direct contact with the boron arsenide BAs layer.

4. The structure of claim 3, wherein one of the crystalline boron arsenide BAs layer and the 3C polytype silicon carbide layer comprises an implantation layer comprising hydrogen and/or helium.

5. The structure of claim 1, further comprising a temporary support attached to the crystalline layer of boron arsenide BAS.

6. The structure of claim 5, wherein the temporary support comprises an adhesive thermal tape.

7. The structure of claim 5, further comprising a layer of stressor material between the temporary support and the crystalline boron arsenide BAs layer.

8. An electronic device integrating the structure according to claim 1.

9. The electronic device of claim 8, further comprising a semiconductor substrate integrating at least one electronic circuit juxtaposed to the crystalline boron arsenide BAs layer.

10. The electronic device of claim 9, wherein the crystalline boron arsenide BAS layer is joined to the semiconductor substrate by direct bonding.

11. The electronic device of claim 8, further comprising a transistor including a channel in the crystalline boron arsenide BAS layer.

12. A method of fabricating a structure for microelectronic applications, comprising:
providing a 3C polytype silicon carbide layer having a flat surface; and
growing a crystalline boron arsenide BAs layer on the silicon carbide layer, the silicon carbide layer and the crystalline boron arsenide BAs layer having two dimensions each of at least 2 cm respectively along two directions normal to each other and included in an extension plane parallel to the flat surface of the silicon carbide layer.

13. The method of claim 12, further comprising forming a detachment layer and detaching, at the detachment layer, at least a portion of the crystalline boron arsenide BAS layer with respect to at least one portion of the silicon carbide layer.

14. The method of claim 13, wherein the forming the detachment layer comprises introducing a light species into the silicon carbide layer so as to define therein a weakened plane before the growing the crystalline boron arsenide layer, followed by a heat treatment for splitting the silicon carbide layer into two parts at the weakened plane.

15. The method of claim 14, wherein the growing the crystalline boron arsenide BAs layer on the silicon carbide layer is carried out at a temperature below 850 C.

16. The method of claim 14, further comprising growing the crystalline boron arsenide BAs layer to a thickness of between 100 μm and 2000 μm.

17. The method of claim 13, wherein the forming the detachment layer comprises introducing a light species into the crystalline boron arsenide BAs layer so as to define therein a weakened plane, followed by a heat treatment for splitting the boron arsenide layer into two parts at the weakened plane.

18. The method of claim 17, further comprising growing the crystalline boron arsenide BAs layer to a thickness of between 0.5 μm and 5 μm.

19. The method of claim 13, wherein the forming the detachment layer comprises covering the silicon carbide substrate with a layer of van der Waals material before the growing the crystalline boron arsenide BAs layer.

20. The method of claim 19, further comprising forming the layer of van der Waals material to comprise a graphene layer.

21. The method of claim 19, further comprising attaching an intermediate support to the boron arsenide layer and detaching the boron arsenide BAs layer from the silicon carbide layer by applying traction to an intermediate support attached to the boron arsenide layer.

22. A method of fabricating a microelectronic circuit, comprising:
Forming a structure for microelectronic applications using the method according to claim 12;
joining the crystalline boron arsenide BAs layer to a semiconductor substrate in which a plurality of electronic circuits are integrated; and
separating the electronic circuits from each other after the joining the crystalline boron arsenide BAs layer to the semiconductor substrate.
